(19) United States
(12) Patent Application Publication
(10) Pub. No.: US 2026/0331175 A1
(43) Pub. Date: Oct. 22, 2026

(54) NAND FLASH MEMORY STRUCTURE, MANUFACTURING METHOD, AND ELECTRONIC DEVICE

(71) Applicant: Huahong Integrated circuit (Chengdu) Corporation, Chengdu (CN)

(72) Inventors: Yufei SHU, Chengdu (CN); Shaokang YAO, Chengdu (CN); Yishan WU, Chengdu (CN)

(73) Assignee: Huahong Integrated circuit (Chengdu) Corporation, Chengdu (CN)

(21) Appl. No.: 19/386,278

(22) Filed: Nov. 12, 2025

(30) Foreign Application Priority Data
Apr. 16, 2025 (CN) 2025104772729

(51) Int. Cl. G11C 16/04; G11C 16/08

(52) U.S. Cl. CPC G11C 16/0483; G11C 16/08

(57) ABSTRACT

A NAND flash memory structure comprising a memory cell region, even selection transistors, odd selection transistors, and a page buffer, a manufacturing method making it, and a NAND flash memory electronic device are disclosed. The memory cell region comprises even storage strings and odd storage strings, the even storage strings are provided with even bitlines, and the odd storage strings are provided with odd bitlines. The even and odd selection transistors are integrated within the memory cell region and are used to control a turning-on state of the even and odd bitlines, respectively. The page buffer is coupled to the memory cell region through the even and odd selection transistors, to program data signals into or read from the memory cell region. This structure can effectively reduce the number of high-voltage transistors required for the page buffer, thereby significantly reducing the overall layout area of the NAND flash memory structure.

### FIELD OF THE INVENTION

The present disclosure relates to the field of semiconductor integrated circuit design and manufacturing, and particularly relates to a NAND flash memory structure, a manufacturing method making it, and a NAND flash memory electronic device.

### BACKGROUND OF THE INVENTION

In the information-driven era, the importance of data storage has become increasingly pronounced. Among various storage technologies, NAND flash memory stands out as a key component of nonvolatile memory, also known as NVM, commanding over 90 percent of the NVM market. Its widespread presence can be seen in a broad range of electronic devices, including broadly used smartphones and tablets, enterprise-level data centers, and security surveillance systems, all of which rely on NAND Flash technology.

As technology continues to advance, the growing demand for high-capacity storage at lower costs has driven the adoption of vertically stacked architectures, commonly referred to as 3D NAND Flash Memory. By stacking memory cells along the vertical axis, this approach significantly reduces chip area and lowers production costs. Compared to traditional planar architectures, referred to as 2D NAND Flash Memory, the 3D stacking technique enables greater memory cell density per unit area, which translates into substantially higher storage capacity. However, when it comes to lower or medium-capacity NAND Flash Memory, typically under 128 gigabytes, the planar architecture—also known as Plane NAND Flash Memory or 2D NAND Flash Memory—still remains the dominant choice. This preference arises from its more cost-effective nature within this capacity range, while still satisfying the performance needs of targeted application scenarios.

Because of intrinsic physical constraints, chip area is directly linked to storage capacity, as each memory cell occupies a fixed space. To overcome this limitation, 3D NAND Flash Memory utilizes vertical stacking to compress chip dimensions. In contrast, 2D NAND Flash Memory is restricted by its flat structure and cannot capitalize on vertical space. Consequently, manufacturers seeking price competitiveness often rely on architectural refinement to contrain chip area in planar designs.

Among these architectural considerations, the design of the page buffer plays a vital role. Two major configurations are widely employed: the interleaving architecture and the all bitline architecture. The interleaving architecture is especially effective in conserving space, allowing advanced functions to be implemented within a compact chip area and helping to reduce production costs. Meanwhile, the all bitline architecture delivers superior read-and-write speed performance, enabling rapid data access. For applications where read-and-write speed is not critical, but cost minimizing is essential, the interleaving architecture is typically favored. These devices aim to maximize storage capacity within tight cost limitations rather than prioritizing data transfer speed.

Despite its efficiency in space utilization, the interleaving architecture still occupies a significant portion of the chip area. As the demand for smaller and more integrated products continues to grow, further enhancement of the interleaving architecture is necessary. The challenge lies in reducing the chip area while preserving the cost advantages, a goal that continues to drive progress and innovation in NAND flash technology.

It should be noted that the above introduction to the technical background is only for the convenience to the understanding of those skilled in the art and to facilitate the collective addressing of the problem of excessive area consumption associated with conventional NAND flash memory structures.

### SUMMARY OF THE INVENTION

The present disclosure provides a NAND flash memory structure, a manufacturing method of making it, and a NAND electronic device.

A first embodiment of the present disclosure provides a NAND flash memory structure. The structure comprises a memory cell region, even selection transistors, odd selection transistors, and a page buffer. The memory cell region comprises even storage strings and odd storage strings, the even storage strings are provided with even bitlines, and the odd storage strings are provided with odd bitlines. The even selection transistors and the odd selection transistors are integrated within the memory cell region and are arranged respectively to control a turning-on state of the even bitlines and a turning-on state of the odd bitlines. The page buffer is coupled to the memory cell region through the even selection transistors and the odd selection transistors, to program data signals into or read from the memory cell region.

In some examples of the present disclosure, each of the even storage strings and the odd storage strings comprises storage transistors, a source selection transistor, and a drain selection transistor, and the storage transistors are configured in a NAND string form. A gate of the source selection transistor receives a source selection signal, a first extremity of the source selection transistor is connected to a first end of the storage transistors, and a second extremity of the source selection transistor is connected to a common-source line. A gate of the drain selection transistor receives a drain selection signal, a first extremity of the drain selection transistor is connected to a second end of the storage transistors, and a second extremity of the drain selection transistor is connected to either the even bitlines or the odd bitlines.

In some examples of the present disclosure, the page buffer comprises high-voltage transistors, and each of the high-voltage transistors is connected to an assembly comprising one even selection transistor and one odd selection transistor.

In some examples of the present disclosure, the even storage strings and the odd storage strings are arranged in an alternating configuration, and the even bitlines and the odd bitlines are arranged in an alternating configuration.

In some examples of the present disclosure, one even selection transistor and one odd selection transistor disposed adjacent to said even selection transistor are arranged in a staggered configuration with respect to a routing direction of a selection signal line, and the selection signal line comprises an even selection signal line and an odd selection signal line. Gates of the even selection transistors are connected to the even selection signal line, gates of the odd selection transistors are connected to the odd selection signal line, and the even selection signal line and the odd selection signal line are arranged in a parallel configuration.

In some examples of the present disclosure, during a read operation, a single read action selects either the even selection transistors or the odd selection transistors, for gating.

In some examples of the present disclosure, during a program operation, a single program action selects either the even selection transistors or the odd selection transistors, for gating.

In some examples of the present disclosure, the even storage strings and the odd storage strings constitute a two-dimensional planar architecture.

A second embodiment of the present disclosure provides a method for manufacturing a NAND flash memory structure, the method comprises, configuring even storage strings and odd storage strings within a memory cell region, the even storage strings are provided with even bitlines, and the odd storage strings are provided with odd bitlines; disposing even selection transistors and odd selection transistors at an edge area of the memory cell region, and controlling a turning-on state of the even bitlines and a turning-on state of the odd bitlines, respectively; and coupling a page buffer to the memory cell region through the even selection transistors and the odd selection transistors, to program data signals into or read from the memory cell region.

A third embodiment of the present disclosure provides a NAND flash memory electronic device comprising a NAND flash memory structure as described in any one of the examples provided in the first embodiment of the present disclosure.

As described above, the NAND flash memory structure, the manufacturing method, and the electronic device of the present disclosure have the following beneficial effects:

The present disclosure introduces a novel NAND flash memory structure based on an interleaving architecture. By integrating even and odd selection transistors along the edge of the memory cell region, the corresponding even and odd bitlines are independently controlled. This enables the page buffer to utilize only a single set of high-voltage transistors, with each transistor simultaneously driving a group of even and odd selection transistors. As a result, the total number of high-voltage transistors required in the page buffer is significantly reduced, leading to a substantial decrease in the overall layout area of the NAND flash memory structure. Compared to conventional interleaving architectures, the proposed NAND flash memory structure reduces the page buffer area by approximately 20%, and by up to 50% relative to the traditional all bitline architecture.

### BRIEF DESCRIPTION OF DRAWINGS

The accompanying drawings are provided to facilitate a further understanding of the embodiments of the present disclosure. They form part of the specification and serve to illustrate the embodiments described herein, collectively elucidating the principles of the present disclosure in conjunction with the textual description. It is readily apparent that the drawings described below are merely exemplary representations of certain embodiments of the present disclosure.

FIG. 1 shows a schematic circuit diagram of a current NAND flash memory structure for a page buffer with all bitline architecture.

FIG. 2 shows a schematic layout of the NAND flash memory structure shown in FIG. 1.

FIG. 3 shows a schematic circuit diagram of a current NAND flash memory structure for a page buffer with interleaving architecture.

FIG. 4 shows a schematic layout of the NAND flash memory structure shown in FIG. 3.

FIG. 5 shows a schematic circuit diagram of a NAND flash memory structure having a page buffer with an interleaving architecture according to the embodiments of the present disclosure.

FIG. 6 shows a schematic layout of the NAND flash memory structure according to the embodiments of the present disclosure.

### REFERENCE NUMERALS

10 Storage Region
11 Page Buffer with All Bitline Architecture
12 Decoding Circuit Region
20 Storage Region
21 Page Buffer with Interleaving Architecture
22 Decoding Circuit Region
30 Memory Cell Region
301 Storage Transistor
302 Source Selection Transistor
303 Drain Selection Transistor
304 Common-Source Line
305 Virtual Storage Transistor
306 Even Selection Transistor
307 Odd Selection Transistor
31 Page Buffer
311 High-Voltage Transistor
32 Decoding Circuit Region

### DETAILED DESCRIPTION OF THE INVENTION

The embodiments of the present disclosure will be described below. Those skilled can easily understand disclosure advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

It should be further understood that the terms “include” and “comprise” indicate the existence of the described features, elements, steps, or components, but do not exclude the existence or addition of one or more other features, elements, steps, or components.

Features described and/or illustrated in connection with one embodiment may be used in the same or similar manner in one or more other embodiments, combined with features of other embodiments, or serve as alternatives to features of other embodiments.

For example, when the embodiments of the present disclosure are described in detail, for ease of description, the cross-sectional view showing the device structure will not be partially enlarged according to the general scale, and the schematic diagram is only an example, which should not limit the scope of protection. In addition, the actual production should include the length, width and depth of the three-dimensional space dimensions.

For the convenience of description, spatial relation terms such as “below”, “under”, “beneath”, “on”, “above”, “up”, etc. may be used herein to describe the relationships between an element or feature and other elements or features. It will be understood that these spatial relationship terms are intended to encompass directions/orientations of the device in use or operation other than those depicted in the drawings. In addition, when a first layer is referred to as being “between” a second layer and a third layer, the first layer may be the only layer between the second and third layers, or there may more layers between the two layers.

In the context of this disclosure, the structure described with a first feature “on top” of a second feature may include embodiments where the first and second features are formed in direct contact, or it may include embodiments where additional features are formed between the first and second features such that the first and second features are not in direct contact.

It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the components' layout may also be more complicated.

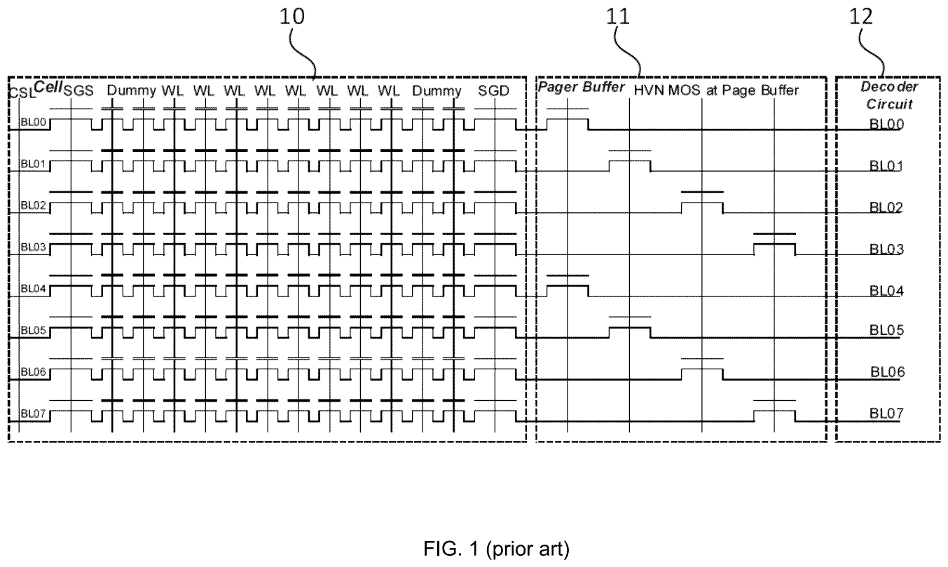

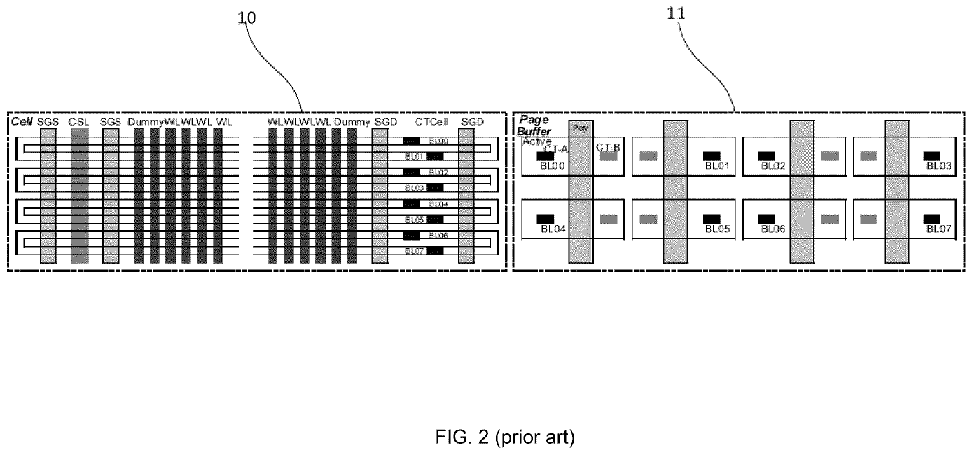

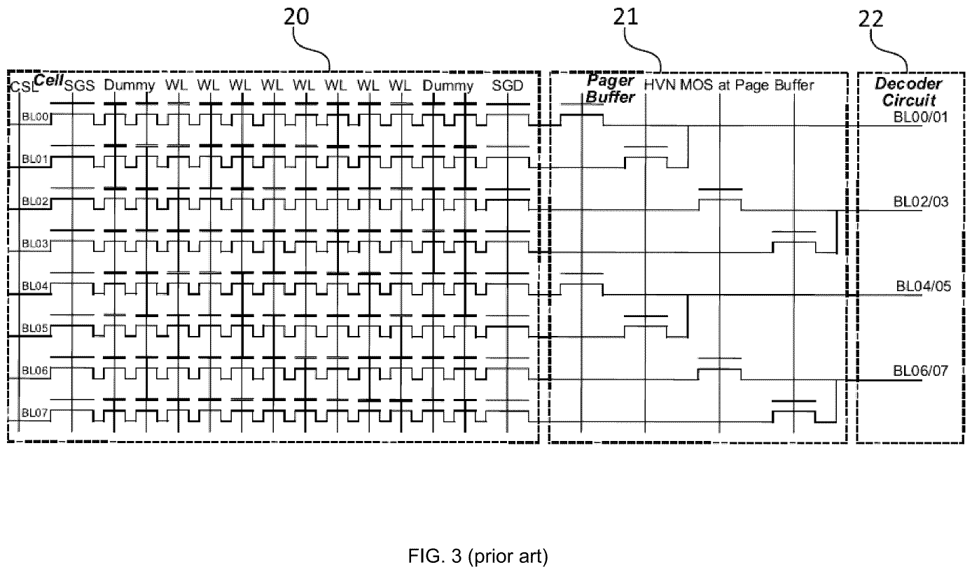

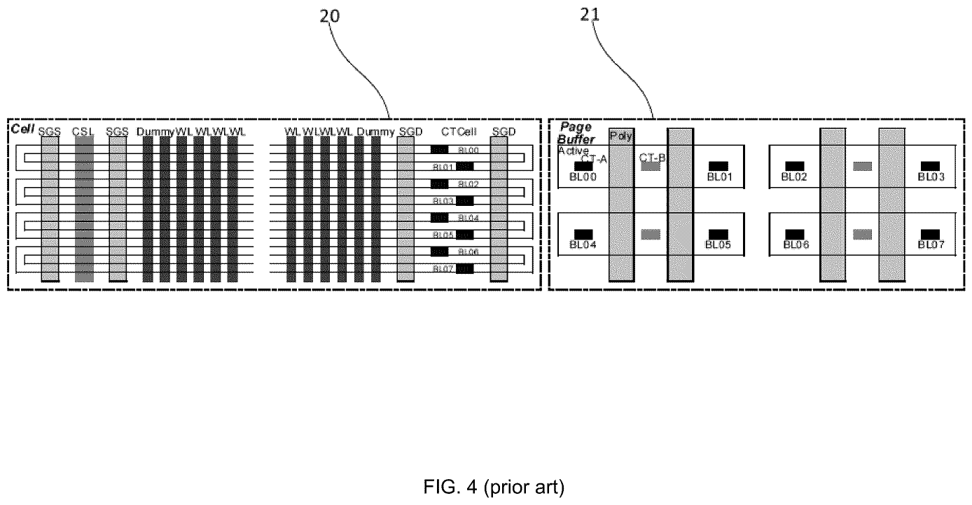

The NAND Flash page buffer architecture generally falls into two categories: the all bitline architecture, shown in FIGS. 1 and 2, and the interleaving architecture, depicted in FIGS. 3 and 4. The NAND Flash device based on the all bitline architecture has a storage region 10, a page buffer 11, and a decoding circuit region 12. In contrast, the interleaving architecture comprises a storage region 20, an interleaved page buffer 21, and a decoding circuit region 22. The all bitline architecture delivers superior read-and-write speed performance, enabling rapid data access. The interleaving architecture is especially effective in conserving space, allowing advanced functions to be implemented within a compact chip area and helping to reduce production costs. In practice, the selection between the two architectures depends on specific application requirements. For applications where read-and-write speed is not critical, but minimizing cost is essential, the interleaving architecture is typically favored. As the demand for smaller and more integrated products continues to grow, further enhancement of the interleaving architecture is necessary. The present disclosure provides an improved NAND flash memory structure based on an interleaving architecture, to reduce chip area while maintaining cost efficiency.

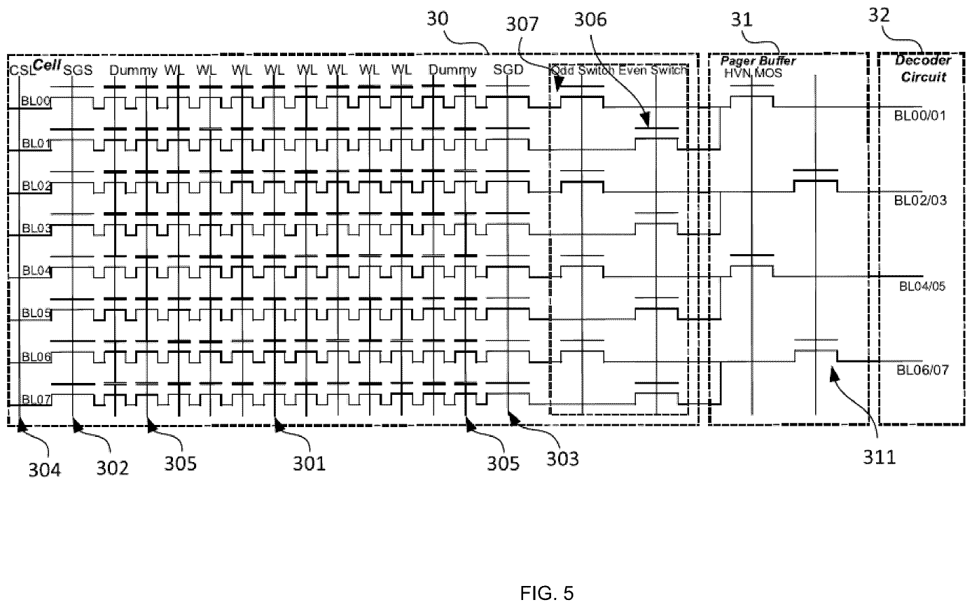

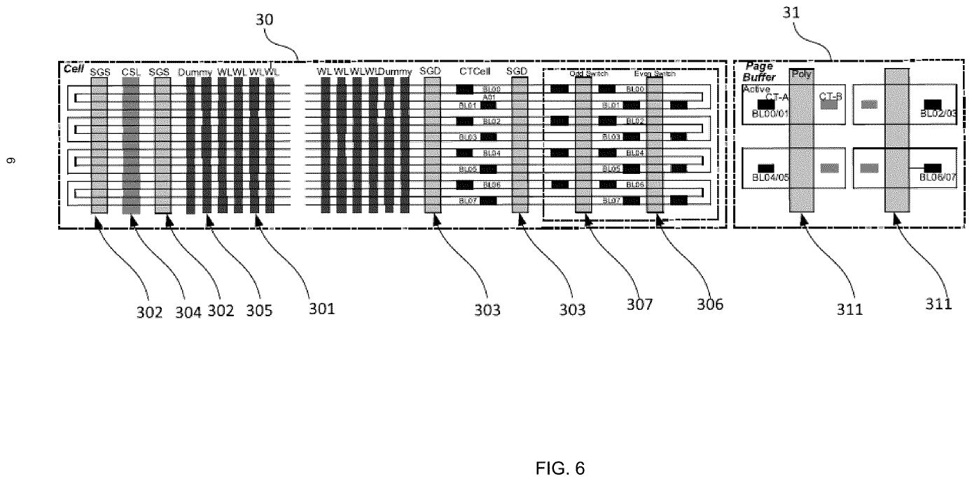

According to an embodiment of the present disclosure, as shown in FIGS. 5 and 6, a NAND flash memory structure, comprises a memory cell region 30, even selection transistors 306, odd selection transistors 307, and a page buffer 31. The memory cell region 30 comprises even storage strings and odd storage strings, the even storage strings are provided with even bitlines, and the odd storage strings are provided with odd bitlines. The even selection transistors 306 and the odd selection transistors 307 are integrated within the memory cell region 30 and are arranged respectively to control a turning-on state of the even bitlines and a turning-on state of the odd bitlines. The page buffer 31 is coupled to the memory cell region 30 through the even selection transistors 306 and the odd selection transistors 307, to program data signals into or read from the memory cell region 30.

In one embodiment, the even storage strings and the odd storage strings are arranged in an alternating configuration, to constitute a two-dimensional planar architecture.

In one embodiment, each of the even storage strings and the odd storage strings comprises storage transistors 301, a source selection transistor 302, and a drain selection transistor 303, and the storage transistors 301 are configured in a NAND string form. Each one of control gates of the storage transistors 301 is connected to a bitline WL. A gate of the source selection transistor 302 receives a source selection signal SGS, a first extremity of the source selection transistor 302 is connected to a first end of the storage transistors 301, and a second extremity of the source selection transistor 302 is connected to a common-source line 304. A gate of the drain selection transistor 303 receives a drain selection signal SGD, a first extremity of the drain selection transistor 303 is connected to a second end of the storage transistors 301, and a second extremity of the drain selection transistor 303 is connected to either the even bitlines or the odd bitlines.

For example, the even storage strings and the odd storage strings may each comprise a NAND string of 16 floating-gate type storage transistors connected in series, and the gate structure of the floating-gate type storage transistors may comprise a sequential stack comprising a tunneling oxide layer, a floating-gate polycrystalline silicon layer, a gate dielectric layer (e.g., a silicon oxide layer, a silicon nitride layer, or a silicon oxide/silicon nitride/silicon oxide (ONO) composite dielectric layer), and a control gate (e.g., a polycrystalline silicon or a metal layer, etc.). It should be noted that the number of floating-gate type storage transistors may be scaled up to 32, 64, or more numbers and is not limited to the examples listed herein. The thickness of the tunneling oxide layer may be 5 nm to 10 nm, the thickness of the floating-gate polycrystalline silicon layer may be 20 nm to 50 nm, the thickness of the gate dielectric layer may be 80 nm to 100 nm, etc., and the thickness of the control gate may be 100 nm to 300 nm, etc.

The source selection transistor 302 and the drain selection transistor 303 may be disposed at two ends of the even storage strings and the odd storage strings, respectively. The gate of the source selection transistor 302 receives the source selection signal SGS to perform switch control. The gate of the drain selection transistor 303 receives the drain selection signal SGD to perform switch control.

In one embodiment, the even storage strings and the odd storage strings are arranged in an alternating configuration, and the even bitlines and the odd bitlines are arranged in an alternating configuration. This alternating configuration of the even and odd bitlines can effectively reduce crosstalk between adjacent bitlines, decrease the coupling capacitance between them, and enhance read accuracy.

In one embodiment, as shown in FIGS. 5 and 6, each side of the even storage strings and the odd storage strings is provided with a virtual storage transistor (DUMMY) 305.

In one embodiment, each of the even selection transistors 306 and its adjacent odd selection transistor 307 are arranged in a staggered configuration with respect to a routing direction of a selection signal line, and the selection signal line comprises an even selection signal line (Even Switch) and an odd selection signal line (Odd Switch). As shown in FIGS. 5 and 6, it is preferred to arrange the odd selection transistors 307 at a location closer to the storage transistors 301 relative to the even selection transistors 306 at the same side of the storage transistors 301. The gates of the even selection transistors 306 are connected to the even selection signal line to perform switch control. The gates of the odd selection transistors 307 are connected to the odd selection signal line to perform switch control. The even selection signal line and the odd selection signal line are arranged in a parallel configuration, and the spacing between the even selection signal line and the odd selection signal line may be, for example, 100 nm to 200 nm. The staggered configuration of each even selection transistor 306 and its adjacent odd selection transistor 307 facilitates routing of the even and odd selection signal lines, minimizing interference. Additionally, it effectively mitigates parasitic capacitance loss and reduces signal delay.

The even selection transistors 306 and the odd selection transistor 307 operate at a voltage and occupy an area significantly smaller than the operating voltage and area of the high-voltage transistor 311 within the page buffer. The even selection transistors 306 and the odd selection transistors 307 may be an NMOS transistor comprising a source, a drain, and a gate. The gate comprises a gate dielectric layer and a gate electrode layer, such as an oxide layer (the thickness of which may be, for example, 3 nm to 10 nm) or a high-k dielectric (such as HfO₂). The gate electrode layer may, for example, be a polycrystalline silicon layer or a metal gate layer (such as TiN/TaN, etc.). The operating voltage of the even selection transistors 306 and the odd selection transistors 307 may be, for example, no greater than 5V. The even selection transistors 306 and the odd selection transistors 307 may be prepared using the same process as the memory cell region.

In one embodiment, during a read operation, a single read action selects either the even selection transistors 306 or the odd selection transistors 307, for gating. Specifically, as shown in FIG. 5, during the read operation, either the even selection transistors 306 or the odd selection transistors 307 is turned on via the corresponding even or odd selection signal lines. Concurrently, a corresponding high-voltage transistor 311 within the page buffer 31 is gated to activate either the even storage strings or the odd storage strings, thereby enabling the retrieval of the storage state through the output current of the corresponding bitline.

In one embodiment, during a program operation, a single program action selects either the even selection transistors 306 or the odd selection transistors 307, for gating. Specifically, as shown in FIG. 5, during the program operation, either the even selection transistors 306 or the odd selection transistors 307 is turned on via the corresponding even or odd selection signal lines. Concurrently, a corresponding high-voltage transistor 311 within the page buffer 31 is gated to activate either the even storage strings or the odd storage strings, to perform the program action of the even and odd storage strings by applying a voltage to the control gates of the storage transistors 301 to tunnel the electrons into the floating-gate polycrystalline silicon layer, or by applying a voltage to the control gates and the drains of the storage transistors 301 simultaneously to enter the electrons into the floating-gate polycrystalline silicon layer by a thermo-electron effect. Similarly, during the erasing operation, either the even selection transistors 306 or the odd selection transistors 307 is turned on via the corresponding even or odd selection signal lines. Concurrently, a corresponding high-voltage transistor 311 within the page buffer 31 is gated to activate either the even storage strings or the odd storage strings, to perform the erase action of the even and odd storage strings by applying a voltage to the control gates of the storage transistors 301 to tunnel the electrons in the floating-gate polycrystalline silicon layer into the substrate, or by applying a voltage to the control gates of the storage transistors 301 and the substrate simultaneously to enter the electrons in the floating-gate polycrystalline silicon layer into the substrate.

In one embodiment, as shown in FIGS. 5 and 6, the page buffer 31 comprises a number of high-voltage transistors 311, and each of the high-voltage transistors 311 is connected to an assembly comprising one even selection transistor 306 and one odd selection transistor 307.

In one embodiment, the NAND flash memory structure further comprises a decoding circuit region 32. A gate of each of the high-voltage transistors 311 receives a high-voltage switching signal, a first end of the high-voltage transistor 311 is connected to a shared output of an assembly that consists of one even selection transistor 306 and one odd selection transistor 307, and a second end of the high-voltage transistor 311 is connected to the decoding circuit region 32.

As an example, the high-voltage transistors 311 may have an withstand voltage of 20 V or more, and the high-voltage transistors 311 may have a structure such as laterally diffused metal oxide semiconductor (LDMOS).

Referring to FIGS. 3 and 5, the page buffer of FIG. 3 needs to be provided with two sets of high-voltage transistors 311 corresponding to the even storage strings and the odd storage strings, respectively, and the high-voltage transistors 311 need to occupy a larger area. As shown in FIG. 5, the NAND flash memory structure of the present disclosure integrates the even and odd selection transistors along the edge of the memory cell region, the corresponding even and odd bitlines are independently controlled, enabling the page buffer 31 to utilize only a single set of high-voltage transistors, with each transistor simultaneously driving a group of even and odd selection transistors. As a result, the total number of high-voltage transistors required in the page buffer 31 is significantly reduced (50% reduction compared to the structure of FIG. 3). Additionally, the even selection transistors 306 and odd selection transistors 307 are low-voltage transistors, whose total occupied area is much smaller than the area occupied by the high-voltage transistors 311, leading to a substantial decrease in the overall layout area of the NAND flash memory structure. Compared to conventional interleaving architectures, the proposed NAND flash memory structure reduces the page buffer area by approximately 20%, and by up to 50% relative to the traditional all bitline architecture. Taking a 1G-capacity two-dimensional NAND Flash as an example, replacing the conventional all bitline architecture with the novel staggered page buffer architecture proposed in the present disclosure can reduce the chip area by approximately 8%, thereby allowing an increase of about 70 additional chips per wafer.

The present disclosure further provides a method for manufacturing a NAND flash memory structure, comprising configuring even storage strings and odd storage strings within a memory cell region 30, the even storage strings are provided with even bitlines, and the odd storage strings are provided with odd bitlines; disposing even selection transistors 306 and odd selection transistors 307 at an edge area of the memory cell region 30, and controlling a turning-on state of the even bitlines and a turning-on state of the odd bitlines through the even selection transistors 306 and the odd selection transistors 307, respectively; and configuring a page buffer 31, the page buffer 31 is coupled to the memory cell region 30 through the even selection transistors 306 and the odd selection transistors 307, to program data signals into or read from the memory cell region.

In one embodiment, the even selection transistors 306 and the odd selection transistors 307 may be prepared using the same process as the memory cell region.

The present disclosure also provides a NAND flash memory electronic device comprising a NAND flash memory structure as described above.

As an example, the electronic device may be a solid state hard disk, a mobile device (e.g., a smartphone), a PC computer or laptop, a tablet computer, a smart home, a new energy vehicle, and an Internet of Things terminal.

As described above, the NAND flash memory structure, the manufacturing method, and the electronic device of the present disclosure have the following beneficial effects:

By integrating even and odd selection transistors along the edge of the memory cell region, the corresponding even and odd bitlines are independently controlled. This enables the page buffer to utilize only a single set of high-voltage transistors, with each transistor simultaneously driving a group of even and odd selection transistors. As a result, the total number of high-voltage transistors required in the page buffer is significantly reduced, leading to a substantial decrease in the overall layout area of the NAND flash memory structure.

Therefore, the present disclosure effectively overcomes various shortcomings in the existing technology and has high industrial utilization value.

The above-mentioned embodiments are for exemplarily describing the principle and effects of the present disclosure instead of limiting the present disclosure. Those skilled in the art can make modifications or changes to the above-mentioned embodiments without going against the spirit and the range of the present disclosure. Therefore, all equivalent modifications or changes made by those who have common knowledge in the art without departing from the spirit and technical concept disclosed by the present disclosure shall be still covered by the scope of the present disclosure.

1. A NAND flash memory structure, comprising:
a memory cell region, comprising even storage strings and odd storage strings, wherein the even storage strings are provided with even bitlines, and the odd storage strings are provided with odd bitlines;
even selection transistors and odd selection transistors, integrated within the memory cell region and arranged respectively to control a turning-on state of the even bitlines and a turning-on state of the odd bitlines; and
a page buffer, coupled to the memory cell region through the even selection transistors and the odd selection transistors, to program data signals into or read from the memory cell region.

2. The NAND flash memory structure according to claim 1, wherein each of the even storage strings and the odd storage strings comprises storage transistors, a source selection transistor, and a drain selection transistor, and wherein the storage transistors are configured in a NAND string form;
wherein a gate of the source selection transistor receives a source selection signal, a first extremity of the source selection transistor is connected to a first end of the storage transistors, and a second extremity of the source selection transistor is connected to a common-source line; and
wherein a gate of the drain selection transistor receives a drain selection signal, a first extremity of the drain selection transistor is connected to a second end of the storage transistors, and a second extremity of the drain selection transistor is connected to either the even bitlines or the odd bitlines.

3. The NAND flash memory structure according to claim 1, wherein the page buffer comprises high-voltage transistors, wherein each of the high-voltage transistors is connected to an assembly comprising one of the even selection transistors and one of the odd selection transistors.

4. The NAND flash memory structure according to claim 1, wherein the even storage strings and the odd storage strings are arranged in an alternating configuration, and the even bitlines and the odd bitlines are arranged in an alternating configuration.

5. The NAND flash memory structure according to claim 1, wherein one of the even selection transistors and one of the odd selection transistors disposed adjacent to said one of the even selection transistors are arranged in a staggered configuration with respect to a routing direction of a selection signal line, wherein the selection signal line comprises an even selection signal line and an odd selection signal line, wherein gates of the even selection transistors are connected to the even selection signal line, wherein gates of the odd selection transistors are connected to the odd selection signal line, and wherein the even selection signal line and the odd selection signal line are arranged in a parallel configuration.

6. The NAND flash memory structure according to claim 1, wherein during a read operation, a single read action selects either the even selection transistors or the odd selection transistors, for gating.

7. The NAND flash memory structure according to claim 1, wherein during a program operation, a single program action selects either the even selection transistors or the odd selection transistors, for gating.

8. The NAND flash memory structure according to claim 1, wherein the even storage strings and the odd storage strings constitute a two-dimensional planar architecture.

9. A method for manufacturing the NAND flash memory structure according to claim 1, comprising:
configuring the even storage strings and the odd storage strings within the memory cell region, wherein the even storage strings are connected with the even bitlines, and the odd storage strings are connected with the odd bitlines;
disposing the even selection transistors and the odd selection transistors at a side area of the memory cell region, and controlling respectively the turning-on state of the even bitlines and the turning-on state of the odd bitlines through the even selection transistors and the odd selection transistors; and
coupling the page buffer to the memory cell region through the even selection transistors and the odd selection transistors, to program the data signals into or read from the memory cell region.

10. An electronic device comprising the NAND flash memory structure according to claim 1.
